(19) United States
(12) Patent Application Publication
(10) Pub. No.: US 2023/0341488 A1
(43) Pub. Date: Oct. 26, 2023

(54) LOW POWER STIMULATED EMISSIONS NMR USING RABI TRANSITIONS FOR THE DETECTION OF MOLECULES [BIOLOGICS WITH 15N, 14N, 1H, AND 13C] THROUGH THE USE OF MATCHED FILTER LIBRARIES OF RESONANCE CHARACTERISTICS ASSOCIATED WITH THE MOLECULES

(71) Applicant: AMI RESEARCH & DEVELOPMENT, LLC, Merrimack, NH (US)

(72) Inventors: John T. Apostolos, Lyndeborough, NH (US); William Mouyos, Windham, NH (US); James D. Logan, Candia, NH (US); Walter Chase, Auburndale, NH (US)

(21) Appl. No.: 17/917,011

(22) PCT Filed: Mar. 23, 2021
(86) PCT No.: PCT/US21/23636

§ 371 Date: Oct. 5, 2022

Related U.S. Application Data
(60) Provisional application No. 62/993,164, filed on Mar. 23, 2020.
(60) Provisional application No. 63/028,292, filed on May 21, 2020.

(51) Int. Cl. G01R 33/465

(52) U.S. Cl. CPC G01R 33/465

(57) ABSTRACT

A high-speed, portal-based system that can rapidly identify the presence of viruses such as COVID-19 and its antibodies in vivo. The system uses a low-power, stimulated emissions Nuclear Magnetic Resonance (NMR) effect and associated signal processing to detect the presence of organics characteristic of the virus (such as ¹⁵N, ¹⁴N, ¹H, and/or ¹³C). The walkthrough portal enables non-invasive, real-time screening at a low cost. Detection can be reliably made in vivo when the virus or antibody is present in the saliva, chest, lungs, or other organs at total counts as low as 108 copies per ml.

### REFERENCE TO RELATED APPLICATIONS

The following United States patent publications and issued patents, filed by AMI Research & Development LLC, the assignee of the present application are hereby incorporated by reference:
US-2014/0266209-A1 Detection processing for NQR system
U.S. Pat. No. 8,901,926-B2 Arrangement for multiple frequency, multiple portal NQR detection
U.S. Pat. No. 8,912,788-B2 Low power stimulated emission nuclear quadrupole resonance detection at multiple reference power levels
U.S. Pat. No. 9,052,371-B1 Combinational nuclear quadrupole resonance (NQR) and nuclear magnetic resonance (NMR) apparatus with linear frequency chirp detected signals
U.S. Pat. No. 8,401,297B1 Neuromorphic parallel processor
U.S. Pat. No. 9,170,311-B2 Nuclear quadrupole resonance system
US-2019/0346531A1 Orientation independent antennas with direction finding for remote keyless entry” (presently assigned to Antenum, Inc.)

The following International Patent Publication is also hereby incorporated by reference:
WO-2015138012-A1 Nuclear quadrupole resonance system

The following patents are also of interest and incorporated by reference:
U.S. Pat. No. 8,710,837-B2 Shipping container explosives and contraband detection system using nuclear quadrupole resonance
U.S. Pat. No. 8,674,697-B2 Long distance explosive detection using nuclear quadrupole resonance and one or more monopoles

### BACKGROUND

As the current COVID-19 pandemic rages worldwide, there is an acute need for detection and treatment of viruses. The most common methods of detection require collecting a body fluid sample, such as a nasal or blood sample, which are physically intrusive to the patient. The collected samples are then transported to a laboratory to be cultured before applying intensive processes such as nucleic detection of the virus itself (via Polymerase Chain Reaction (PCR) or sequencing), microscopy (via immunofluorescence- or immunoperoxidase-assay or electron microscopy), or antibody detection (via blood plasma assays and the like).

### SUMMARY

We have realized that certain electromagnetic principles originally used to detect explosives can be adapted to detect viruses and/or their antibodies rapidly and with minimal invasion. These principles can be implemented in a walk-through or drive through portal that can deliver on-the-spot results extremely rapidly, such as in a minute or two, with no need to send anything such as a body fluid sample to a lab.

This invention adapts the driving chirp waveform, filtering [both analog & digital] and the neuromorphic signal processing pattern recognition used to detect explosives to detecting viruses of interest. Its principle of operation is fundamentally different than previous Nuclear Magnetic Resonance (NMR) viral detection, in that this uses a Continuous Wave (CW) approach where the transmitter is on when receiving, opposed to a pulse approach that turns the transmitter off when receiving and relies on free decay (spontaneous emissions) instead of stimulated emissions.

Analogous principles are also likely usable in scenarios where similar equipment can be used to treat the virus, as well.

More particularly, the SEE-QR (Stimulated Enhanced Emissions Quadrupole Resonance) technologies described in the above-referenced patents and patent applications describe a portal-based system to detect explosives. Many of the systems and methods described in those patents and patent applications relied on stimulating Nuclear Quadrupole Resonance (NQR) emissions from the nitrogen in explosives (most explosives have nitrogen) using power levels safe for humans. A pattern recognizer (which may be a neuromorphic pattern recognizer) identified the small resonance signals (difficult to discern given the large background noise) coming from even tiny amounts of explosive materials. The system(s) were shown to detect a wide variety of nitrogen-containing explosives.

The drawback of the strictly NQR approach, however, was that it could not detect nitrogen in vapors. As a result, later developments, also described in the referenced patents and patent applications look to other resonance methodologies, specifically Nuclear Magnetic Resonance (NMR). An NMR approach requires a static magnetic field, in addition to using the receive antenna and hardware in the NQR-based systems. See for example, the system described in U.S. Pat. No. 9,052,371 referenced above.

It is known, for example, that relatively high power NMR fields can detect the proteins characteristic of viruses. Researchers at the Massachusetts Institute of Technology recently published such a report entitled “The transmembrane conformation of the influenza B virus M2 protein in lipid bilayers”, Nature Scientific Reports (2019) 9:3725 (Mandala, V. K. et al.) In that report they demonstrate detection of the Influenza B M2 protein in various lipids (DLPE, POPC:POPG) via various NMR modalities (CP, DP, INEPT). Distinct spectra for that protein were observed for a range of concentrations in parts per million (ppm) for least ¹⁵N and ¹³C. However, the NMR laboratory equipment used in that study were relatively high frequency (800-900 MHz) and very high fields (on the order of 14 to 21 Tesla).

We have realized that principles analogous to those used at MITcan be used to detect a virus and/or its related antibodies in a vapor, a liquid sample, or even within the host body, but with the distinction that such a system would instead be based on observing responses to low frequency RF emitted within low-strength magnetic fields. The generated static magnetic field can be perhaps only 20 gauss (as compared to the 14 to 20 Telsa fields used in the MIT study). The emitted RF frequencies for expected viral responses can range from 100 kHz to 3 MHz (with an expected mapping of 100 ppm to 1 MHz).

The detection systems also use signal processing to look for unique signatures or “fingerprints” of a virus—that is, by detecting responses for a defined set of RF resonances, or sweeping across a range thereof associated with the virus of interest and/or related antibodies. In one example, the system matches against a library of known carbon and nitrogen resonances characteristic of a virus such as COVID-19. Such a detection system should have sufficiently rapid signal processing hardware and/or software to be capable of producing a result quickly, such as in one (1) minute or less after someone had stood in the portal for 60 seconds.

A drive-through system is also feasible using the same underlying principles.

A standoff system is also believed to be possible, whereby the system scans a crowd and look for the presence of the virus and/or its related virus.

When the virus is detected, a decision can be made to operate in another mode to treat it. In particular, a high resolution scan may optionally be used to determine the exact resonant frequencies and the phases needed. In this emission mode, a conjugate of the detection transmit waveform is synthesized to deliver all of the emitted power coherently to the virus. The emitted resonant energy, targeted to affect only a particular virus of interest, may have a field strength sufficient to break apart at least its outer lipid membrane, thereby disabling it.

### BRIEF DESCRIPTION OF THE DRAWINGS

FIG. 1 is an isometric view of a portal and a high level system block diagram.

FIG. 2A is an internal plan view and FIG. 2B is a cross sectional view of the portal showing the arrangement of wire segments and coils in more detail.

FIG. 3 is a high level schematic of the direct current and chirp signal generation and detection components.

FIG. 4 is a flow diagram for control of the DC generator connected to the coils and RF chirp transmitter connected to the wire segments.

FIG. 5 illustrates a person inside the portal

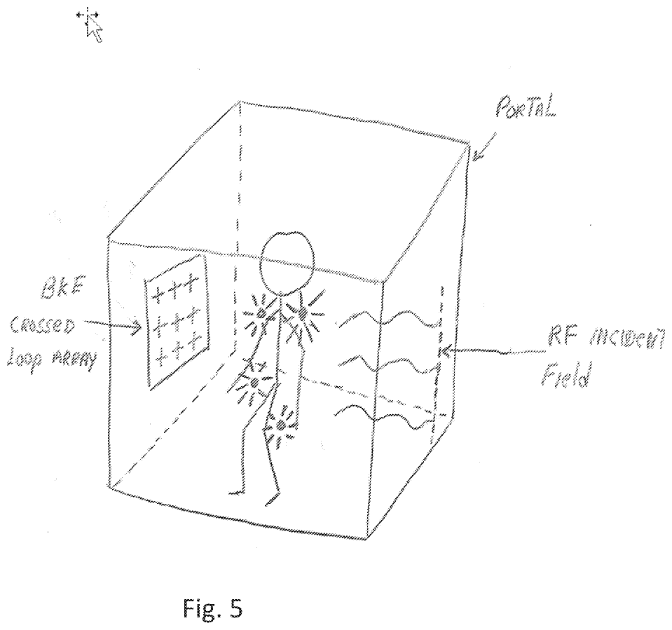

### DETAILED DESCRIPTION OF PREFERRED EMBODIMENTS

A high-speed, portal-based system identifies the presence of viruses such as COVID-19 and its antibodies in vivo. The system uses low-power, stimulated emissions Nuclear Magnetic Resonance (NMR) to detect Rabi Transition resonances associated with viruses. The portal enables non-invasive, real-time screening for specific virus types. Detection may be reliably made in vivo when the virus or antibody is present in the saliva, chest, lungs, or other organs at total counts as low as 108 copies per ml.

The basic idea is to provide a structure or method for detecting a substance using two or more conductive surfaces, preferably arranged in parallel and spaced apart from one another. One or more segments of conductive wire are disposed adjacent each of the surfaces, within the space between the two surfaces. Two sets of multi-turn coils are furthermore also disposed between the two surfaces, typically such that the windings of each coil are disposed between one of the conductive wires and one of the surfaces. The coils may be arranged as a Hemholtz coil pair.

A suitable continuous-excitation signal, such as a linear continuous chirp signal, is applied to the wire segments in various modes to determine the characteristics of a substance located between the conductive surfaces.

With the coils activated to generate a static magnetic field, emissions from the wire segments at certain frequencies induce an NMR effect in any substance located between the two conductive surfaces. The result increases the sensitivity of known NMR systems to detect a wide range of substances of interest.

In vivo detection is possible by adapting NMR techniques previously used to detect nitrogen in liquid state explosives inside the body. These NMR techniques were needed as molecules of liquid state explosives do not have an inherent magnetic field as do solid state explosives. This NMR approach can however, be used to detect not just in vivo liquid explosives, but also viral bodies and their antibodies as well in-vivo.

This belief is supported by the fact that hi-power, much larger NMR systems, with very strong magnets have been used by research labs to identify and study viruses. The idea that NMR technology can discern viruses and similar biologic matter is thus well understood science. The approach described herein is different, as it uses very low power and much smaller magnets to make NMR virus detection safe for humans, and to scale down the system to the size of a walk-through portal.

The applications for this enhanced system may include virus detection “on the fly” as a person walks thru the portal, or a vehicle drives through a drive-through version. The system will generate a stimulus static magnetic field with magnetic flux density (B) of 2 mT. This exposes the subject undergoing screening to only 0.005 of the 400 mT International Commission on Non-Ionizing Radiation Protection established limit for general public exposure to static magnetic fields—(See for example, International Commission on Non-Ionizing Radiation Protection. Guidelines on limits of exposure to static magnetic fields. Health Physics 96.4 (2009): 504-514.

In one example embodiment, detection may be based on resonant spectroscopy fingerprints produced by ¹⁵N, ¹⁴N, ¹H, and ¹³C characteristic of a virus. These resonances are expected to have amplitudes, phases, and center frequencies indicative of the structure of the virus and the viral envelope. In the case of antibody detection, discrimination is based on the molecular structure of the specific antigen-binding fragments located on the Fab portion of the antibody and on the epitopes or reactive sites of the antigen.

The detection method, in particular, may take advantage of the fact that the electrons of ¹⁵N, a common form of Nitrogen, contain information on overall molecular “shape” of a particular virus, that is unique for each virus structure. ¹⁵N electrons are exposed to a static magnetic field and the stimulus interrogation wave, reach a higher excited energy level, and then emit coherent energy in the form of a radio wave when they transition back to ground state. It is this stimulated emission that contains the information about the molecular composition of the virus. As the ¹⁵N electrons of a particular objective molecule are arranged in a unique way, their stimulated emissions exhibit a characteristic fingerprint. The return radio wave is received and processed through a series of matched filters to eliminate the noise and detect whether the objective molecule is present above the detection threshold. Unlike an explosive molecule, a virus has a much more complicated, unique three dimensional shape that is expected to provide, for example, a characteristic RF phase response.

Detection of the viral resonance is also dictated by the Signal to Noise (SNR) which results in the familiar “continuous wave radar” expected Probability of Detection (P_{D})/Probability of False Alarms (P_{FA}) as follows:

Information provided by Draper Laboratory indicates there are 108 copies of corona in 1.0 cc of endotracheal aspirate.

In one example with a static magnetic field of 100 gauss, the RF magnetic field is 10 gauss, and the ambient noise is approximately −204 dBW. With the portal shielding against the local environment (>50 dB) the resulting signal levels for ¹⁵N, ¹⁴N, and ¹³C have been calculated to be:

| | |
|---|---|
| ¹⁴N | −143 dBW |
| ¹⁵N | −166 dBW |
| ¹³C | −142 dBW |

With these signals the SNR is predicted to be greater than 12 dB enabling the same “NQR”-type processing to be used for virus detection.

An ESR approach, perhaps also coupled with NMR, can be applied to detect viruses and/or antibodies in vapors, liquid samples, as well as human tissue.

System Design Considerations

As described below, we have realized that a portal structure and corresponding transmitter and detection processing can be used to observe a Nuclear Magnetic Resonance (NMR) effect induced in an organic vapor or liquid such as that produced by a virus.

1. Portal Design and Chirp Signal Generation

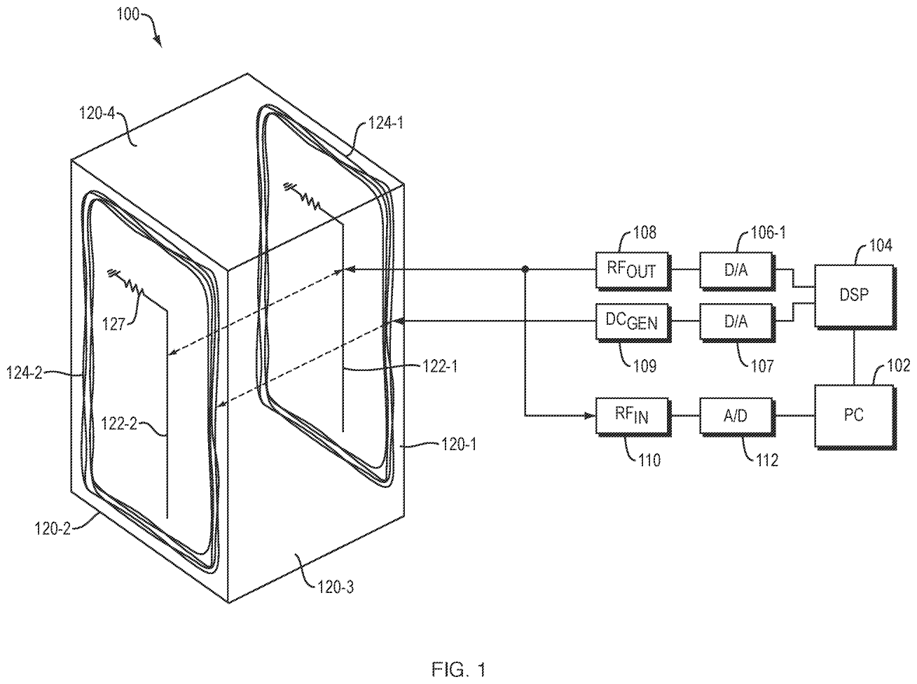

FIG. 1 is a high-level diagram of the components of a detection system according to the teachings herein.

In general, the system may include a portal 100 into which materials of interest are placed. Here the portal 100 consists of four walls 120-1, 120-2, 120-3, 120-4 arranged as right side, left side, bottom and top. At a minimum, the inner surfaces of the walls 120 are formed of or coated with a conductive material, although the walls may be a solid metal such as aluminum as well.

A programmable data processor such as a personal computer (PC) 102 controls a radio frequency (RF) chirp transmitter 108, direct current (DC) generator (DC current f source) 109, Digital Signal Processor 104 and other circuits such as filters (not shown in FIG. 1) and D/A converters 106, 107 to generate various emission control signals. The generated signals are coupled to transmission line(s) or other conductors disposed within the portal walls to cause electromagnetic fields to be generated within the portal. Receiver circuitry 110 detects an NMR-induced response of a material disposed within the portal. The system then digitizes the response signals with one or more A/D converters 112 and forwards the detected response to the PC 102 typically after further processing by a Digital Signal Processor (DSP) 104. The DSP 104 and/or PC 102 then make a decision as to whether there are certain types of materials in the portal, and displays the result.

Although specific configuration details will vary, the personal computer (PC) 102 may have the typical central processing unit (CPU), memory, disk and/or other mass storage devices, and a display (not shown). The PC 102 stores and executes software programs that implement the functions described herein. A power supply (not shown) provides power to the PC 102 as well as to the other components of the system. An input/output (I/O) subsystem, which may be a peripheral board plugged into the PC via a suitable interface includes a number of digital to analog converters and analog to digital converters.

In addition, the PC may itself include one or more Digital Signal Processor (DSP) hardware chips and/or software platforms to implement transmit signal generation and receive signal detection functions.

In the transmit direction, the PC 102 controls the DSP 104 and/or D/A 106, to generate desired chip signals that include one or more NMR frequencies of interest. More particularly, each of many RF signals may include a linear chirp signal, for example, a sinusoidal signal having an instantaneous frequency that changes linearly with time. The instantaneous frequency of each chirp signal may be mathematically represented as

$${ω}_{instantaneous} = 2 π {F}_{start} + 2 π ( \frac{B W}{T} ) t$$

where Fₛₜₐᵣₜ is an initial frequency, BW is a bandwidth (frequency range in hertz) of the chirp, and T is the duration of the chirp.

In one implementation for an NMR mode, the chirp signal generated by RF transmitter 108 may have a BW of 100 kHz and T may be 2 seconds.

The chirp signals preferably originate as digital signal data computed and/or stored by the PC 102. Each digital chirp signal, associated with one or more NMR frequencies of interest, is fed to the D/A 106, is low-passed filtered, and amplified. As explained in more detail below, multiple analog chirp waveforms with alternating power state illuminations may be generated at a given instant in time via multiple D/As, filters, and amplifiers operating in parallel in the Radio Frequency Output (RFout) circuits 108.

The electromagnetic field(s) generated in response to the chirped RF signals are then made incident on whatever substance is contained in the portal 100, causing coherent radio frequency emissions from the contents. The response signal(s) from the portal contain the transmitted energy, reflected energy, and the chirp signal(s) and are further processed in an NQR mode to determine the presence of materials exhibiting a nuclear quadrupole resonance.

As will be described in more detail below, the DC generator 109 may be selectively enabled with the RF generator 108 to send a current to coil pair 124-1, 124-2 to operate the portal in an NMR mode.

Signals returned from the portal 100 at receiver 110 are fed to corresponding circuits and A/D converters 112 to provide digital response signals back to the DSP 104 and/or PC 102 for signal processing. The receiver processing may include down conversion, demodulation (dechirping), matched filtering, and other detection processing.

Waveforms emitted in the portal may have other polarizations, which induced by having additional wire loops of different configurations, such as slant linear or crossed loops. By operating in these different modes should improve the ability to detect viruses having different physical orientations.

More details of the signal generation, detection and processing, as well as alternative system architectures and components are also described in the patents and patent applications mentioned previously.

2. Portal Excitation Design

Also of interest in FIG. 1 is the use of two different excitation structures for emitting signals into the portal 100.

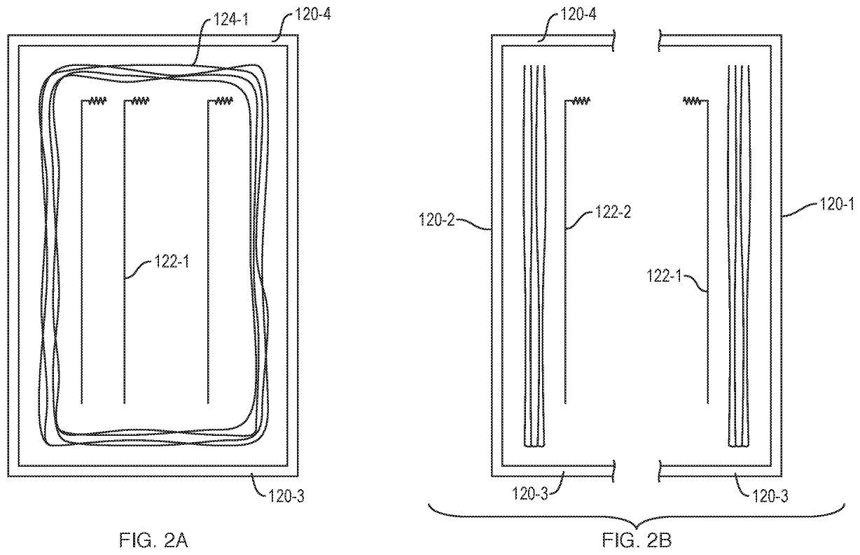

Two or more conductive wires 122-1, 122-2 are a first type of signal emitter, typically disposed within the portal adjacent both a portal right wall 120-1 and left wall 120-2. The conductive wire segments are disposed as straight line wire segments that may be individually terminated via resistors 128 or may be connected together at the roof and arranged as balanced lines (as shown in FIG. 2). The portal top 120-4 and bottom 120-3 walls also act as an RF shield. The wire segments 122 are each located in-board of and spaced apart from a respective one of the side walls 120-1, 120-2. Although only one wire segment is shown adjacent each wall, it is understood that there are typically several such wire segments disposed in parallel along each side wall 120.

Also disposed within the portal is a second type of emitter structure comprising a pair of wire coils 124-1, 124-2. In one example, each coil 124-1, 124-2 has between 100 and 200 turns disposed between a respective one of the walls 120-1, 120-2 and a respective one of the wire segments 122-1, 122-2. The coils may be arranged as an two identical magnetic coils in a configuration known as a Hemholz coil. The turns of the coils 124-1, 124-2 are embedded in fit inside the portal along its sides as seen in FIG. 1. The coils 124-1, 124-2 are energized with a DC signal to generate a static magnetic field in the portal 100 enable an MRI/NMR mode of operation.

In one example for a portal of approximately 8 feet high and 3 feet wide, a current of 10 amps may be sent through each of the coils 124-1, 124-2 to generate a 20 Gauss static field inside the portal 100 for/NMR mode operation. In this mode, the emitted NMR chirp signal frequency via chirp transmitter 108 will be scaled down to around 100 KHz to 3 MHz. Since 100 kHz is at the bottom range of the prior NQR detection system, all the receiver processing methodologies of that NQR system still apply.

In a dual mode portal also having an NQR mode, the detection system described above disables coils 124-1, 124-2 and only activates RF transmitter 108 to emit a continuous incident electromagnetic wave via wires 122 using continuous wave (CW) chirp signals generated by transmitter 108 while at the same time detecting the coherent energy of the resulting Rabi oscillations, also via wires 122. The coherent integration enables detection of a wide range of explosives using relatively low power CW chirp waveforms.

In a similar manner this methodology is applied to operation in an NMR mode using a low power continuous wave (CW) chirp generated by transmitter 108 but with the coil 124 also energized by DC generator 109. Prior art MRI systems typically use a 15,000 Gauss field to detect hydrogen at a free induction decay frequency of 64 MHz. We instead replace the expensive 15,000 Gauss field with a much lower field and are able to detect the lower frequency Rabi oscillations with the coherent processing the same as that used in the NQR mode.

The result increase the sensitivity of known Magnetic Resonance Imaging (MRI) systems and enable the use of multinuclear NMR spectroscopy to detect a wide range of substances of interest.

In addition, the NMR coils 124-1, 124-2 each have a relatively high inductance, such as 0.125 Henries each. This high coil inductance is preferred so that that the presence of coils 124-1, 124-2 does not adversely affect the operation of the conductors 122 in the NQR mode.

It is also observed that the specific magnetic field strength emitted by the coils 124-1, 124-2 affects the expected resonant frequencies for different materials in the NMR mode. Thus the expected NMR emission frequencies can be changed by changing the DC power level emitted by generator 109. It may be desirable in some implementations to operate the system in a couple of different NMR field strengths to increase the number of materials of interest that can be detected by the system.

3. Transmit and Receive Filtering: Detection Processing

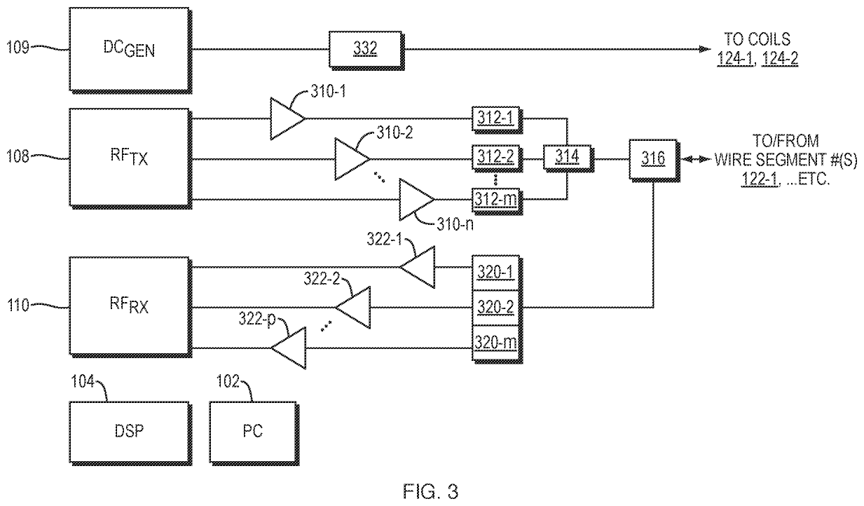

FIG. 3 is a high level diagram of transmitter and receiver analog circuits. Transmitter 108 (RFout) is responsible for generating the linear frequency chirp signals and may include several amplifiers 310-1, 310-2, . . . , 310-n, filters 312-1, 312-2, . . . , 312-m, reactive combiner/multiplexer(s) 314 and directional coupler 316. The resulting chirp signals are fed to the conductive wire segments 122.

On the receive side, signals picked up by the conductive wire segments 122 are fed through directional coupler 316 to one or more receive filters 320-1, 320-1, . . . , 320-m and amplifiers 322-1, 322-2, . . . , 322-p. The exact number and arrangement of filters and amplifiers on both the transmit and receive legs depends on the specific materials of interest, how many resonances are to be excited simultaneously, system cost considerations, and other factors. Several different architectures are described in the co-pending patents and patent applications referenced elsewhere herein.

Also shown in FIG. 3 is the transmit circuitry for DC generator 109 responsible for generating the DC signal to generate the static magnetic field via coils 124-1, 124-2. An amplifier or other current control 332 may control the exact current level applied to the coils 124-1, 124-2 and thus the strength of the resulting static magnetic field in the portal.

Detection processing implemented by the DSP 104 and/or PC 102 can generally be as in any of the detection system(s) described in the other patents and patent applications referenced elsewhere herein. In one example:
a chirped waveform is transmitted into the portal,
the response is received and de-chirped and the transmitted wave is cancelled
a set of matched filters for one or more virus of interest are applied
reflections from the portal are rejected
the NMR energy is passed and filtered
the amplitude and/or phase response associated with each resonance is used

Antibodies are a marker that a person has had exposure to a virus. The detection of antibodies may also be used to develop more precise estimate of the person's immune response. A person detected as having only virus, with no antibodies, might be considered to not yet be immune. If only antibodies are detected, then it can be concluded the person is no longer infected. The relative ratio of the two might be used to determine where the person is along the recovery path towards immunity. Repeated measurements in the portal could establish a possible progression path for the patient. AI tools and machine learning could be used to establish the statistical significance of how the antibody/virus ratio varies over time and by outcome.

Furthermore, the system can ascertain to some extent how the viral load varies across the body and where the virus load is high. This location data could contribute to the progression path model, again, through a machine learning process. It could also to symptoms that might soon occur and allow for pre-emptive treatment.

4. Selective Control of Static Magnetic Field for Dual NQR/NMR Modes

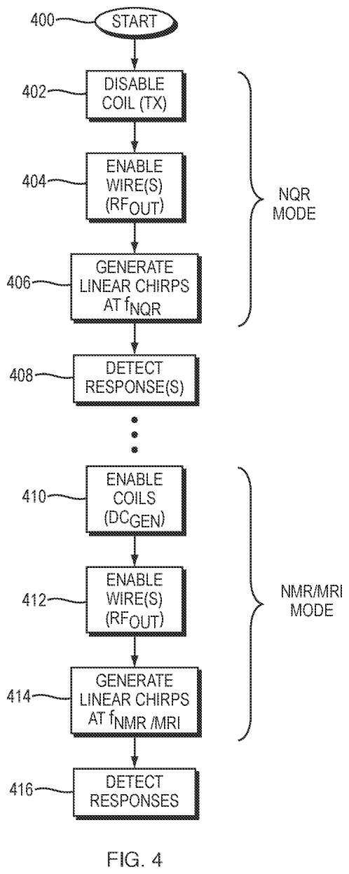

FIG. 4 is an example flow diagram for a control program implemented by the PC 102 to selectively operate the system in either the NQR mode or NMR mode. From an initial state 400, an NQR mode is entered by disabling coil 124 (state 402). Next the RF transmitter TX 108 is enabled (state 404) and chirp waveforms that include NQR frequencies of interest are generated (state 406) and responses detected (state 408). In this state NQR-sensitive materials present in the portal 100, such as may include nitrogen, are determined.

At some other time, the coils 124-1, 124-2 are energized via DC generator 109 (state 410). The RF transmitter 108 is again enabled to couple chirp signals to wire conductors 122 (state 412) but here the chirps generated encompass expected NMR responses of interest (state 414). The responses are detected (state 416) to determine NMR sensitive materials of interest located in the portal.

As explained in the above-referenced patents and patent applications, other approaches can use the expected “human density function” to ignore the effect of the rest of the human body on the detected response

5. Extension to Treatment

We also expect that a conjugate, or “matched emitted waveform” may be used to treat a person infected with a virus.

In this approach, in an acquisition mode the virus detection system may scan over the frequency domain to find sequences of active frequencies corresponding to the matched filter library of a virus. When the virus is detected in a portal, a decision can be made to operate the system in another mode or refer the infected person to another portal that has the added feature of being able to destroy the virus. In this emission mode, a somewhat higher power transmit waveform that is the conjugate of the virus detection waveform is synthesized to deliver the emitted power coherently to the virus. Such a waveform is uniquely absorbed by the virus while minimizing the effect on surrounding tissue. The emitted resonant energy, targeted to affect only a particular virus of interest, may have a field strength sufficient to break apart at least its outer lipid membrane, thereby disabling it.

There might be a characteristic fingerprint, as well, to such a damaged virus that the system could detect. The system could thereby measure the amount of damaged viral content to the intact viral content to assess the progress of the treatment. It is possible that both fingerprints (of intact and disabled viruses) could be measured at one time allowing for such an efficacy measurement to be made during the treatment. Alternatively, the system could iterate, first transmitting the conjugate, then measuring its efficacy.

The measurement and treatment cycles could be repeated until the virus is no longer detected. Alternatively, if it found that such treatment has deleterious side-effects, such side effect might also have identifying fingerprints. As such, data from the treatment efficacy measure could be combined with this data related to side-effects to come up with an optimal treatment program that balanced the costs and benefits of such treatment. Again, A1 and machine learning would be used continuously refine these trade-offs and relate them to other bodily characteristics which might impact the body's ability to deal with the virus. Such characteristics might also be discerned by the system in an scan that may be used to develop a treatment scheme appropriate for the particular patient's condition. For instance, if the person had a previously weakened immune system, making the viral infection more of a threat, then the treatment might be pushed harder to lower the viral load even lower even if such treatment was causing related damage.

The treatment program could vary the intensity of the virus-disabling transmission, or the duration of any one transmission, or the periodicity of such transmissions to achieve the ideal balance between disabling viruses and avoiding side effects, or merely achieve a higher disabled rate for the virus. Alternatively, a subset of the full viral fingerprint might be used in an effort to reduce side effects.

Even if the virus is not completely eliminated, there is still an expected benefit to at least reducing the viral load on the patient, thus allowing the patient's own immune system to “catch up”.

Some of the above-referenced patents explained how the location of a material of interest can be located within the portal by detecting the phases of the response. Such systems might be used to determine for example, if the virus is located in the person's lungs, or is being expelled when they breathe, or is only located on their hands. A person having a highly infected lungs might be directed to a health care facility; a person having only “dirty hands” would be asked to simply wash up.

By the same token, when in transmission mode and trying to disable viruses, such treatment might want to be localized in order to reduce side effects or increase efficacy. In some cases, for example, transmission energy might want to be focused on the lungs but not the head in order to reduce potential side effects and to best target the areas most infected with the virus. Different power levels or duration might be used for different areas of the body.

At some point before, during, or after the transmission treatment, a measurement could be made by the portal of the person's antibody “load”. Because the progression of the disease had been interrupted by the treatment, the antibody level might not have built up to a level as high as those infected persons who rid themselves of the virus on their own. The measured ending antibody level might be useful in categorizing persons into a class of people unlikely to get the virus in the future and thus able to travel or work in more virus-hazardous areas. Of course, it is possible that the antibody level will continue to increase after the treatment perhaps due to stimulation caused by the disabled viruses or other reason.

6. In Vivo Imaging

As a further refinement of the viral detection methodology described above, it is possible to extract spectral signature information as a function of location in the body.

FIG. 1 shows a human body standing in the portal, the emitted RF incident field, and the locations of viral activity which are activated by the RF incident field. Viral activity at different locations can be approximated as one or more coherent point source(s).

A detection system may include an antenna array and associated radio receivers and processing that creates matched filters for the point sources as a function of location in the body. The antenna array may be, in one embodiment, of the type used for the BKE system described in U.S.

Patent Publication 2019/0346531A1 entitled “Orientation independent antennas with direction finding for remote keyless entry”, assigned to Antenum, Inc.

In effect, any position inside the body can be monitored as a potential location of viral activity. More particularly, as in the implementations described above, detection of location may be further improved by leveraging the three-dimensional shape (curvature) of the emitted wavefront(s) may be detectable to provide further information. In one, a library of matched filters may be correlated to the tracks of the separate resonances for ¹⁵N, ¹⁴N, ¹H, and ¹³C characteristic of a virus. If all such resonances appear to originate from the same point, that may give a more accurate picture of whether there is a virus or not.

The antenna array may be, in one embodiment, of the type described in U.S. Patent Publication 2019/0346531A1 entitled “Orientation independent antennas with direction finding for remote keyless entry”, assigned to Antenum, Inc.

7. Other Use Cases.

With the deployment of multiple such scanning machines, they can be connected in a network to provide intelligence on the spread of a virus, its current infection rate, and the effectiveness of any treatment. Such networking would allow A1 and machine learning to be used to study the effect of modulating the various aspects of the treatment program, including duration, power levels, etc.

Viral detections or the lack thereof, could be used to make decisions about permitting or denying entry to controlled areas. This sort of control could be administered via attendants standing by, controlled by a gate or other physical means, or there could be an honor system, whereby a person is notified of their status and asked to leave the area by a recording.

Users of the portal might also have a smartphone with an app that tracks social distancing. The portal could interact with the app and automatically notify the app if a portal user was seen to have the virus of interest. After such updating of the app, others will corresponding apps that come in contact with the infected person could be notified of that potentially infectious contact event. If the user had no smartphone, nor an app tracking social distancing, this could be determined beforehand and building access and portal access could be denied.

A biometric system could be used in conjunction with the portal. Such a system might be based on facial recognition, passcode, or fingerprint. If a person were diagnosed as having the virus, yet showed up again at the original portal, or another networked portal, and was still in an infected state, a proper authority could be notified. Such a biometric, whether linked to a person's identity or just used for portal purposes could be used to collect data related to that one person with such data being collected from one or more networked portals. For instance, if a person passed through a portal every day it might be useful to see if their antibody levels remained constant.

The system itself could also create its own biometric for adults by looking at things that remain constant over time such at skeletal structure, brain mass and vital organs size. These would provide a radar cross section (RCS) of the person. This is a radar response where the system gets phase and amplitude information over the entire body and how the signal reflects. The NQR and NMR aspect would be a further detail to see specific composition of those constant structures. This “whole-body biometric” would be developed when someone initially goes into the portal and further refined each time they are scanned. Such a biometric would be very difficult to spoof.

It ia also believed that the system could detect other deleterious anomalies in the bodies besides viruses. For instance, at the cellular level, cancer cells of various types are likely to have a set of resonances and a resulting fingerprint as described above, that would be different from a normal cell. Harmful bacteria would likewise have a fingerprint that could be detected. In both cases, the amount of such material could be estimated and some locational information obtained as well. Transmission treatments as discussed above would possibly work as well on these structures.

Other material or conditions the system might detect would include Alzheimer amyloid plaque, hardened arteries, degenerated cartilage, and similar conditions.

The system could provide a means to measure volumes of various substances circulating in the body. Volumes can be estimated by measuring the signal strength of the received fingerprint. Inferring volume via signal strength would require an estimate of various other factors that could attenuate or affect the amplitude of a fingerprint signal. Such factors might be body fat and body size, These factors might also be quantified by the system and A1 and machine learning would then be used to recalibrate or reconstitute the strength of the fingerprint signal based understanding the effect of these extraneous factors.

Another approach would be to calculate relative measures of volume. For instance, perhaps a relative measure of amyloid tangles compared to brain volume would provide a meaningful metric of the advance of Alzheimer. Here no absolute measurement, per se, would be needed.

Measure of the volume of various substances in the blood could replace or supplement common blood tests. For instance, it might be desirable to understand the patient's level of Vitamin D circulating in blood. As this level is already easily measured via the standard blood test, such blood tests could be used to calibrate the system and correlate Vitamin D fingerprint signal strength with actual levels as determined via a blood tests. Other substances for which absolute or relative volumes of that could be measured by the system include alcohol, glucose, or even water as a means to ascertain hydration levels.

Other real world correlations could look at disease progression. For instance a function could be developed of how much cancer is likely present given a certain cancer fingerprint signal strength. This function could be developed by using information gleaned from surgical procedures or autopsies done soon after system readings of cancer cell fingerprint strength. The results would allow the system to estimate the stage of cancer by looking at the strength of the cancer cell fingerprint signal and comparing that to known cases with calibrated fingerprints. The results would be adjusted for known factors, such as body size, fat content, and other conditions that would have a known impact on the strength of the fingerprint signal.

Blood tests today can look for hundreds of different compounds, diseases, and conditions. Many, if not most, of these conditions could be detected and measured by the system. The analysis of signals to look for this many fingerprints would take significant time and processing power. As such, it would be advantageous for the systems to be cloud-connected such that the signal processing could be done by servers with more processing power than a local machine. This would allow more efficient use of processing power as such centralized systems could run continuously as results came in from around the world, while the processing power in local systems would only be used during the work day. Furthermore, to optimize machine learning and to study the correlations between fingerprints and actual conditions, centralizing data in the cloud would be preferred over local storage.

Other use cases include using the system to scan for pathogens in animals. Pandemics have occurred among livestock populations in recent years resulting in large destruction of such populations to control diseases. Such culling could be done on a more selective basis if it were known which specific animals were infected, which had survived an infection, and which had not been exposed. When used with animals, different safety limits on RF power might be applicable allowing for lower system costs or greater accuracy or speed on the performance side. The system might also be employed with automated equipment used to move the animals depending on test results. That is, animals could be shuttled through a portal, with non-infected or recovered animals being allowed to go into one holding pen, while infected ones were shunted into another area by use of automated gates tied to system results. Such a gating system could, of course, be employed by systems used on people as well.

The system might also mark animals with different statuses for easier handling after testing. This could be an automated paint-marking feature added to the portal, for instance. The system would be set up to catch infections at the earliest possible stage. This might be accomplished by stationing portals permanently in the facility and having a setup whereby animals pass through the portal at least once a day. Stand-off systems and grid systems (larger detection systems laid on the floor that are traveled over and not set up in a portal form) could be more convenient means to monitor the health of large numbers of animals.

The system could also be used on plant matter. In particular, a less robust version of the system could be designed to just look for a plant pathogen such as salmonella or E. coli. Such a system might sit on an assembly line before the packaging step. Bad produce could be handled in the same manner as animals above-shunt bad produce to the side or mark it. The system could process metadata regarding where any given piece of produce came from and feed information relating source and pathogen back to the plant management.

That system could also be used in autopsies, looking for fingerprints of possible causes of death, such as lack of oxygen in the blood, chemicals, or markers that might be associated with a heart attack. The system could also ascertain the possible time of death by looking at the fingerprints of substances that change over time, looking for a sequence of such fingerprints. Again power levels could increased in order to gain a better signal to noise ratio and thus better results.

The system can be used to scan for any number of other disease markers. Some people may be interested in this information and others may not. And they may be interested in just select information. Much like users can set up alerts on Google, he similar sort of system could be set up so that people who passed to portals on a regular basis could be notified if something is out of the ordinary, or they could elect not to know. Such a system could be set up on a subscription basis.

The information from one portal pass could potentially carry immense amount of data about the person who went through. It would take similarly an immense amount of processing to extract all the fingerprints of potential interest. Storage, however, of the data would be relatively cheap allowing portal data to be saved for analysis later.

When the system is used to test for a virus such as COVID-19, it may be advantageous for the portal to have a mechanism to sterilize the portal after the passage of each person. This would also make people more comfortable passing through the portal. If a carrier was detected, an attendant could be alerted to do a more thorough cleaning, or the automated system could do a more thorough cleaning.

Having people wait in line to go through the portal might also strain any social distancing standards in place at the time. Therefore, the system could deploy optical systems and A1 monitor the line of people to be sure they are spaced apart properly. Announcements could be made by the system to encourage distancing.

As many people may have social distance-tracking software on their smartphones, such communications could also be made to people in line more discreetly via the app. Such software would also interface with the system by recording the person's test status and date and time of passage every time they went through the portal.

Software on a person's smartphone might also be used to present maps of where testing stations are located. If a person works in an office building where there is a portal, the app could keep track of the person's travels to and from that building. If testing was only required every third day, for instance, the app would track which days are testing days and provide notification to the person through the app to that effect. If the person was late for work, however, and the portal had a line, the person might be allowed to skip it on the way in, but would require using the portal later in the day. If the person did not use the portal as required, the proper authority would be notified so further action could be taken. If the person did go through the portal on the required morning, the person could go in and out of the building all day without further testing.

The portal, which is capable of creating its own biometric as described above, could insure that the smartphone communicating with the portal is actually associated with the right person.

The portal system could also be used in conjunction with software used to track social distancing and perform contact tracing such as that being offered by Apple and Google or local efforts such as Australia's COVID Safe. If someone supposedly came in contact with a carrier, per the results of such software, they could be instructed to go through a portal under a set schedule, for instance, once a day for the next week.

Such portal passages could be reported to the cloud and fed back into the social distancing software database. Once a person had successfully passed the portal “test”, that person would be considered a safe contact thus helping the system understand how the virus may or may not be spreading between carriers.

Some contact tracking software will not store information in the cloud for privacy reasons but rather locally on each device, Currently, the status of tested-positive person needs to be entered in the system and any contacts with others will then be reported to those that came in contact with the positive person. Using the system, however, such information could be automatically entered if a positive test was performed, and furthermore, a negative test result could also be entered into the status field for anybody who had recently passed successfully through a portal. If the time period from first exposure to becoming contagious is thought to be four days, for instance, such a “clean” status would be associated with a person for that time period after going through a portal. Such a time period would also dictate when a person needed to once again go through a portal.

With clean statuses being stored either in the cloud or locally, the opportunity to use such information on a day-to-day basis would be plentiful. For instance, those with a clean status would be allowed to enter buildings, stores or theatres, if they had a clean status.

Statuses could include infected, clear, possibly infected, possibly clear, antibodies detected-clear, antibodies detected-amount unsure if immune, and similar permutations. People testing positive for an adequate amount of antibodies could be exempt from requirements to pass through the portal. Such portal setups might have a pass-through line whereby persons with proper antibody readings, as recorded on their smartphone, might be able to quickly bypass the portal.

In social situations, one's device could display a local map of people around them and indicate who had a clean status. If one was meeting somebody at a coffee shop, their device could indicate the person's status as they approached. (Today's approaches merely focus on those who had tested negative, not necessarily positive.) It is contemplated that stand-off systems could be designed to scan crowds. These inherently would be less accurate or specific than the results obtained when a person went through a portal alone. But there would still be valuable information collected from such scans. There might, therefore, be another status that could be generated by the system of “probably” clean or “possibly” infected. While not totally specific, there is still valuable information in such designations, which could be uploaded to the cloud or stored locally.

When a new strain of a virus showed up, the data collected for each person might be bifurcated and show the results for each strain of the virus.

From a business standpoint, every store might not be able to afford a portal. They might instead, rely on the status setting of each person coming in who had recently been through a portal. This creates somewhat of a “free rider” problem whereby some establishments would be benefiting from the expense that other establishment went through to set up testing. Therefore, the status information could be kept in a “closed” system. For instance, if a bakery wanted to see customer status information, they would have to subscribe to a service whereby a beacon at their entranceway or elsewhere in their establishment would read the status of each passerby. Each store could have their own policy as to how to handle each status. Alternatively, the entrance of the store might require the customer to pull out their phone and show a QR code that designated their status. Person-to-person use (aka, the coffee shop encounter discussed above), however, could remain free in order ot encourage use of the system.

Testing in a general sense has a much benefit to the general population as it has to the individual being tested. As such, it would be advantageous to encourage more testing. Although the portal itself might be expensive, the incremental cost of one more test is very low. Likewise, the cost to the person being tested, in terms of time, is also quite low. Also, the value of testing to society varies over time—if there is a local outbreak, testing becomes that much more important.

The system could therefore be configured such that people were encouraged to be tested. This could be done whereby a person's app collected testing frequency information and rewards were awarded to people based on their testing habits. Such rewards could be cash, points, lottery tickets, etc. Payments could be made through the government or private sources. Payments could vary by person—somebody working in the building with the portal would not be paid, but someone who had to travel far to get to a portal could be paid or rewarded more.

When infection rates were lower, the ideal periodicity for testing might no longer by the time period over which an infection might incubate. At this point, testing would become more of a social good and a means to monitor the population to look for recurrences. Such a “sampling” regime might be managed by the aforementioned incentive systems designed to keep a desired flow of people going through a network of portals. Such incentives might be designed to get people representing different locations, occupations, or other risk factors, in order to a sampling that would uncover the most likely loci of infections.

≈

Significance to Public Health

The approach described above is expected to have a profound impact on America's testing capabilities and its ability to locate COVID-19 carriers. The advantages over other testing methodologies are as follows:

Real Time Testing—Portal screening is expected to be almost real time. That is, a person could traverse through the portal and get results in a matter of seconds, much as metal detectors work now. This would allow in-the-course-of-daily-life testing whereby portals could be stationed at the entranceway to office buildings, shopping malls, and medical facilities and used to screen out persons trying to enter.

Continuous Testing—With a critical mass of portals installed, the population could be under, in essence, continuous testing. Such continuous, ubiquitous, real-time testing would be a breakthrough in opening the economy and returning to normal life.

Non-Invasive—Our approach is believed to be the only testing approach that does not require any biological matter to be removed from the person (beside X-rays of patients already known to be sick). No saliva, nasal swabs, or blood samples are needed. The non-invasive approach of SEEQR will foster public acceptance of continuous and ubiquitous testing.

No Need to Go To Testing Centers, No Consumables—By being stationed where people will be going anyway, there would be little need to go to a testing center per se, nor to get kits for episodic testing at home.

Drive-Through, Stand-off, and Scanner Implementations—Based on earlier work done with NQR explosives detection, it is believed that a stand-off system could be developed that could scan a crowd of people for COVID-19 from a distance of, perhaps, tens of yards. Furthermore, the standoff approach lends itself to a drive-through format, as well. See for example, at least U.S. Pat. No. 8,710,837 which described adaptation of NQR systems to scanning the contents of metal containers for explosives. Finally, the system could be scaled down to a hand-held scanning system that could be used by trained personnel, using form factors like those described in U.S. Pat. No. 8,674,697 which detected explosives at a distance using NQR and one or more monopoles.

Cost—With an estimated cost of $175,000 each, systems could be placed wherever there is significant foot traffic. Given that testing consists merely of going through the portal, the number of tests produced by any machine could be many hundreds per day. With no significant incremental per-test cost, amortizing the system over the course of one year could yield a cost per test of as little as 50 cents.

Adaptability to Mutations or New Viruses—The system can be easily re-programmed to detect new variants of COVID-19, or other viruses of interest, by merely downloading new templates. Templates may be made in a matter of hours, once a sample has been isolated.

No Healthcare Personnel Needed—Screening is non-contact and does not require medical personnel to be present.

Screening in High Risk Situations—Non-invasive, low-cost, high-throughput screening will be especially valuable for use at extended-care facilities, Navy ships, and entry points to sites with a high probability of transmission such as airports, theatres, or stadiums.

Population Assessment—The portal screening method facilitates both infection and herd immunity assessment by real time sampling for both the presence of the virus and the presence of its antibodies. Screening may be effective for assessing the population of asymptomatic persons or for predicting the extent to which health care facilities will need to develop surge capacity in the coming weeks.

General Applicability—There is very valuable information in the data that would screen out as noise. The investigation and identification of other signals of interest could lead to new advancements in diagnostic medicine.

### REFERENCES

The following documents are also incorporated by reference herein:
John Apostolos, William Mouyos, Judy Feng, and Walter Chase “Low-power stimulated emission nuclear quadrupole resonance detection system utilizing Rabi transitions”, Proc. SPIE 8709, Detection and Sensing of Mines, Explosive Objects, and Obscured Targets XVIII, 87090Q (7 Jun. 2013); https://doi.org/10.1117/12.2021508
International Commission on Non-Ionizing Radiation Protection. Guidelines on limits of exposure to static magnetic fields. Health Physics 96.4 (2009): 504-514
European Union. Directive 2013/35/EU of the European parliament and of the council of 26 Jun. 2013 on the minimum health and safety requirements regarding the exposure of workers to the risks arising from physical agents (electromagnetic fields) (2013): L179/15
Nippon Telegraph and Telephone Corporation, “Electron spin resonance spectroscopy using a superconducting flux qubit featuring high sensitivity and spatial resolution” Science and Core Technology Laboratory Group, Public Relations science_coretech-pr-ml@hco.ntt.co.jp, 2019. [Online]. Available: https://www.ntt.co.jp/news2019/1903e/190329b.html.
Danhier, P. et al. in Electron paramagnetic resonance: a powerful tool to support magnetic resonance imaging research, Contrast Media Mol. Imaging 2015, 10 266-281; Wiley Online Library: 2 Nov. 2014.
Mandala, V. S., et al. “The transmembrane conformation of the influenza B virus M2 protein in lipid bilayers”, Nature Scientific Reports (2019) 9:3725, 6 Mar. 2019.

https://www.companybell.com/seeqr-security/

https://www.prnewswire.com/news-release/seeqr-security/debuts/continuous/wave-explosive-detection-at-ausa-2014-279154031.html

http://www.digitaljournal.com/article/352023

https://www.defensedaily.com/seqr-security-introduces-explosives-detection-portal/uncategorized/

https://twitter.com/SEEQRsecurity

1. A method for detecting presence of a virus comprising:
disposing at least one conductive surface to define a space;
disposing at least one conductive wire within the space adjacent the conductive surface;
driving the conductive wire with a radio frequency transmitter to create a magnetic field within the space at a first power level, to induce a first Nuclear Magnetic Resonance (NMR) response;
detecting resulting first emissions resulting from NMR;
driving the conductive wire with a radio frequency chirp transmitter to create a time magnetic field within the space at a second power level different from the first power level, to induce a second NMR response;
detecting resulting second emissions resulting from the second NMR response;
comparing the first and second detected emissions to determine whether the virus is occupied within the space.

2. The method of claim 1 additionally comprising:
processing the first and second emissions to determine a location of the virus within the space.
